(19) United States
(12) Patent Application Publication
(10) Pub. No.: US 2007/0240868 A1
(43) Pub. Date: Oct. 18, 2007

(54) Air-guiding structure for heat-dissipating fin

(75) Inventors: Chung Wu, Taipei (TW); Meng-Cheng Huang, Taipei (TW)

Correspondence Address: HDSL, 4331 STEVENS BATTLE LANE, FAIRFAX, VA, 22033, US

(73) Assignee: Chaun-Choung Technology Corp.

(21) Appl. No.: 11/404,792

(22) Filed: Apr. 17, 2006

(51) Int. Cl. H05K 7/20

(52) U.S. Cl. 165/185; 361/704; 257/722

(57) ABSTRACT

An air-guiding structure for a heat-dissipating fin is manufactured by providing plural sets of air-guiding portions on each heat-dissipating fin. Each air-guiding-portion includes a plurality of thorns made by stamping. The thorns are arranged non-linearly and oriented to face the inlet or the outlet for external cooling air. With the above arrangement, when the external cooling air enters the inlet of the heat-dissipating fin and passes through the flowing path, as soon as contacting with the thorns of the air-guiding portion, the cooling air is hindered to form a three-dimensional turbulent flow on the heat-dissipating fin. As a result, the duration within which the cooling air stays in the heat-dissipating fin can be extended to efficiently carry the heat source out of the heat-dissipating fins, thereby to improve the efficiency in heat dissipation.

### BACKGROUND OF THE INVENTION

1. Field of the Invention

The present invention relates to an air-guiding structure for a heat-dissipating fin, and in particular to an air-guiding structure for a heat-dissipating fin capable of forming the external cooling air into a three-dimensional turbulent flow and further extending the staying duration of the external cooling air.

2. Description of Prior Art

With the increase of the processing rate and operating frequency of the integrated circuit elements such as CPU, these elements thus can generate more and more heat during operation. Unfortunately, such a high amount of heat will cause harmful effects to all integrated circuit elements. Therefore, it is very important to provide a heat-dissipating fin capable of rapidly dissipating the heat from the integrated circuit elements. After a plurality of heat-dissipating fins are manufactured by press-forming, those heat-dissipating fins are vertically superposed on one another by means of manual operation or machine, so that a flowing path is formed between adjacent two heat-dissipating fins. In this way, a conventional heat-dissipating fin assembly can be obtained. Then, a heat-dissipating fan is mounted at one side of the heat-dissipating fin assembly, so that the heat generated by CPU can be heat-transferred the heat-dissipating fin assembly. Thereafter, with the heat-dissipating fan blowing the cooling air into the heat-dissipating fin assembly, the cooling air can pass through the flowing path between two heat-dissipating fins and carry the heat source out of the heat-dissipating fin assembly.

However, since the cooling air generated by the above heat-dissipating fan rapidly passes through the flowing path between two heat-dissipating fins without any hindrance, the cooling air cannot completely carry the heat source out of the heat-dissipating fin assembly, resulting in the poor efficiency in the heat-dissipating fin assembly.

Therefore, in view of the above the drawbacks, the inventor proposes the present invention to overcome the above problems based on his expert experiences and deliberate researches.

### SUMMARY OF THE INVENTION

The present invention is to provide an air-guiding sure for a heat-dissipating fin. By pressing a metallic plate, the heat-dissipating fin is manufactured to define two long sides and two short sides. Both long, sides are bent toward the same direction to form two partitioning pieces. With the enclosure of the two partitioning pieces, a flowing path is formed in two adjacent heat-dissipating fins. Both short sides are used to be an inlet and an outlet for external cooling air. Each heat-dissipating fin is provided with plural sets of air-guiding portions. Each air-guiding portion comprises a plurality of thorns made by stamping. Each of the thorns is arranged non-linearly and oriented to face both short sides.

With the above arrangement, when the external cooling air enters the inlet of the heat-dissipating fin and passes through the flowing path, as soon as contacting with the thorns of the air-guiding portion, the cooling air is hindered to form a three-dimensional turbulent flow on the heat-dissipating fin. As a result, the duration within which the cooling air stays in the heat-dissipating fin can be extended to efficiently carry the heat source out of the heat-dissipating fins, thereby to improve the efficiency in heat dissipation.

Another, the present invention is to provide an air-guiding structure for a heat-dissipating fin. The plural sets of air-guiding portions can be arranged on the heat-dissipating fin in a regular or irregular way, and the non-linear arrangement of the thorns may be curved or “<”-shaped.

### BRIEF DESCRIPTION OF THE DRAWINGS

FIG. 1 is a perspective view showing the external appearance of the heat-dissipating fin of the present invention;

FIG. 2 is a front view of the heat-dissipating fin of the present invention;

FIG. 3 is a front view showing a second type of arrangement of the air-guiding portions of the present invention;

FIG. 4 is a front view showing a third type of arrangement of the air-guiding portions of the present invention;

FIG. 5 is a schematic view showing the external appearance of the heat-dissipating fin assembly of the present invention mounted to a heat-dissipating fan;

FIG. 6 is a cross-sectional view showing the state in which the heat-dissipating fin assembly of the present invention is used; and

FIG. 7 is a cross-sectional view showing the state in which another embodiment of the present invention is used.

### DETAILED DESCRIPTION OF THE INVENTION

The detailed description and the technical contents of the present invention will be explained with reference to the accompanying drawings. However, it should be understood that the drawings are illustrative but not used to limit the scope of the present invention.

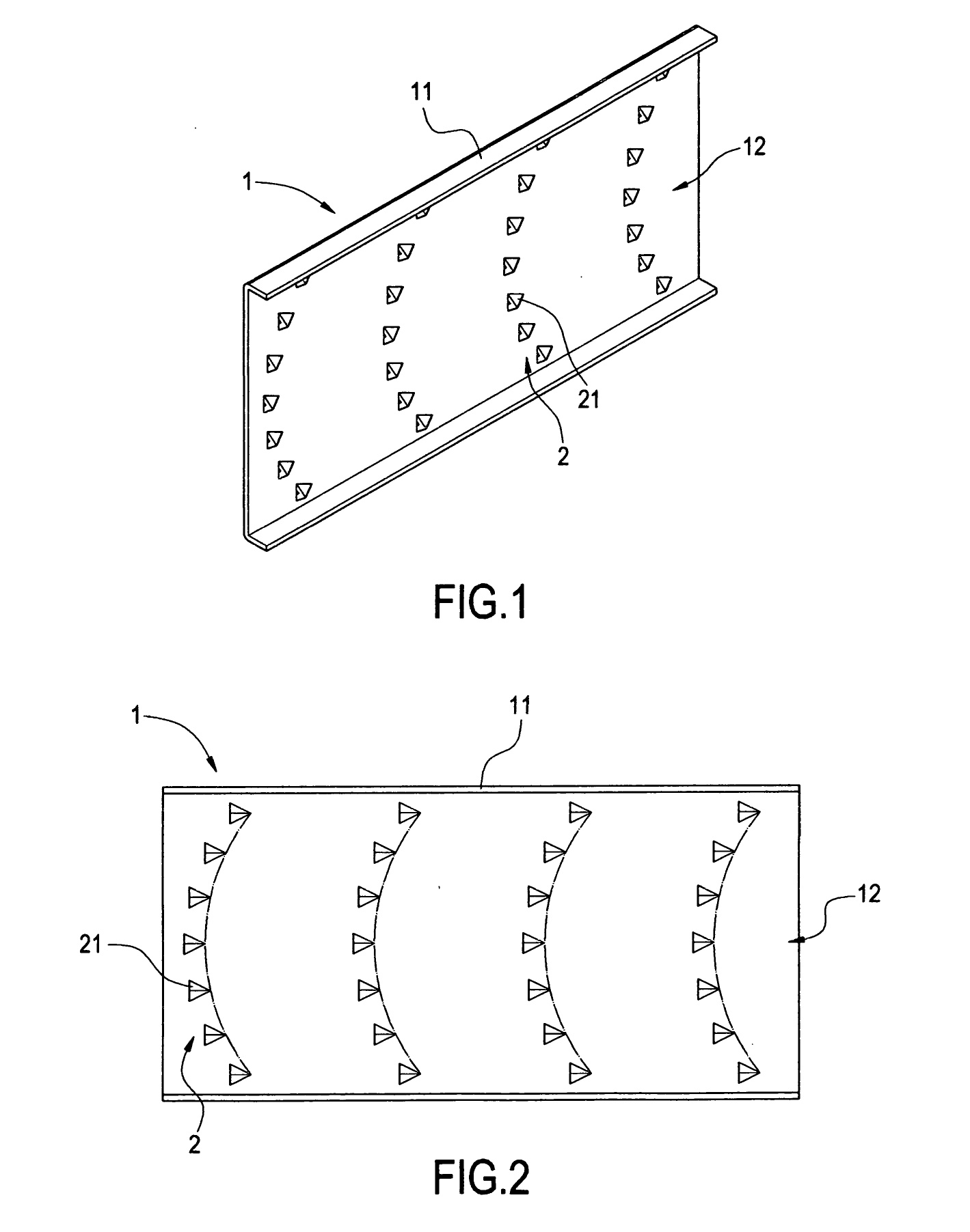

The present invention is directed to an air-guiding structure for a heat-dissipating fin. With reference to FIG. 1, by pressing a metallic plate, the heat-dissipating fin 1 is manufactured to define two long sides and two short sides. Both long sides are bent toward the same direction to form two partitioning pieces. With the enclosure of the two partitioning pieces 11, a flowing path 12 is formed between two adjacent heat-dissipating fins 1. Both short sides are used to be an inlet and an outlet for external cooling air.

With reference to FIGS. 1 and 2, the characteristics of the present invention are as follows. Each heat-dissipating fin 1 is provided with plural sets of air-guiding portions 2. In the present embodiment shown in FIG. 1, four sets of air-guiding portions 2 are provided. Each air-guiding portion 2 comprises a plurality of thorns. The thorn 21 is manufactured by stamping a through hole on the heat-dissipating fin 1 with the unbroken portion connected to one side of the through hole. The plurality of thorns 21 are arranged non-linearly and oriented to face both short sides of the heat-dissipating fin 1. In the first embodiment of the present invention, seven thorns 21 are arranged in a curved manner to form a non-linear arrangement. The concave of the curved arrangement faces the inlet. The four sets of air-guiding portions 2 are regularly arranged at the same intervals.

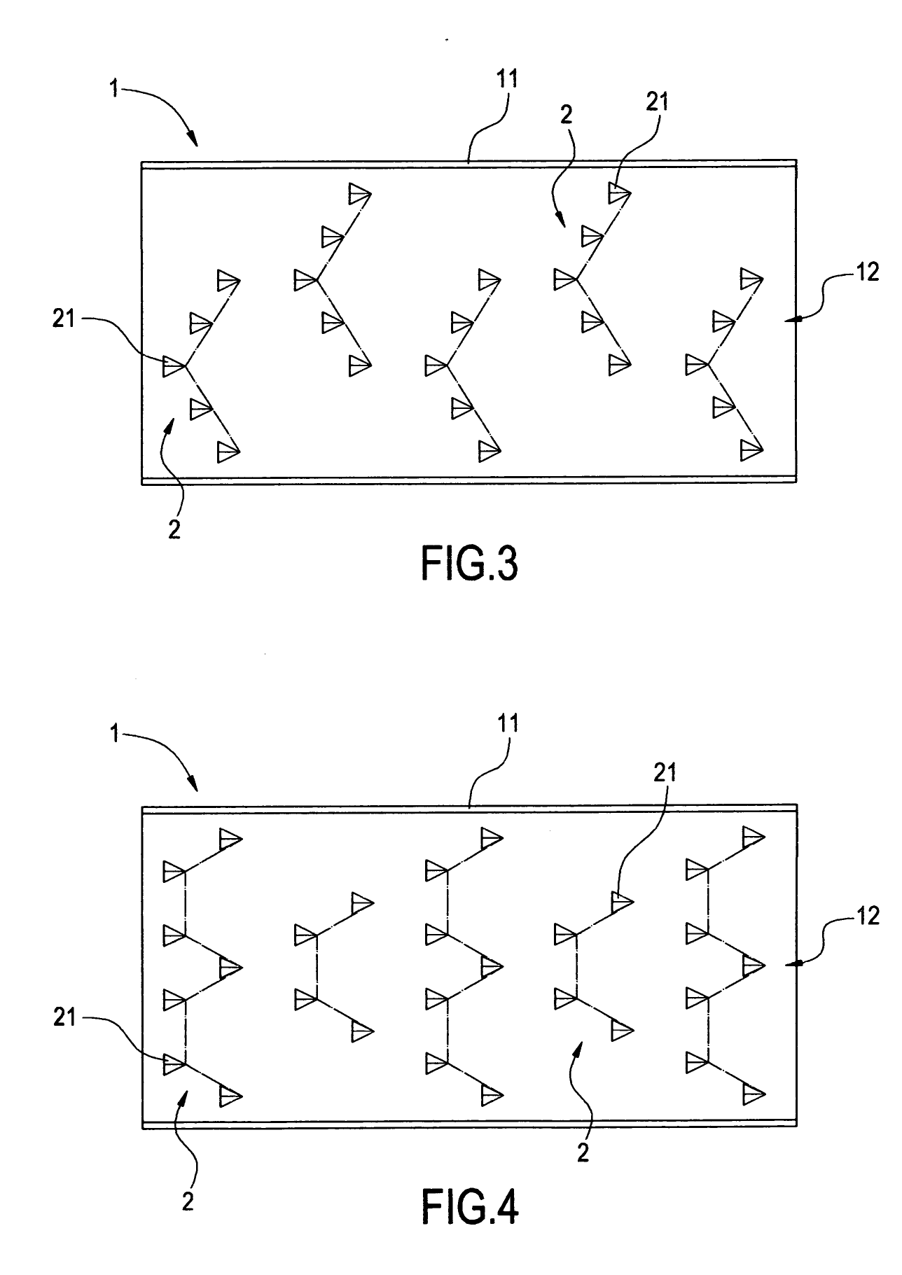

FIG. 3 is a front view showing a second type of arrangement of the air-guiding portions 2 of the present invention. The nonlinear arrangement of the thorns 21 is “<”-shaped. The concave of the “<”-shaped arrangement also faces the inlet. Further, any two adjacent air-guiding portions 2 are staggered. FIG. 4 is a front view showing a third type of arrangement of the air-guiding portions 2 of the present invention. The non-linear-arrangement of the thorns 21 is “[”-shaped. The concave of the “[”-shaped arrangement also faces the inlet. Each air-guiding portion 2 can be arranged in an irregular manner.

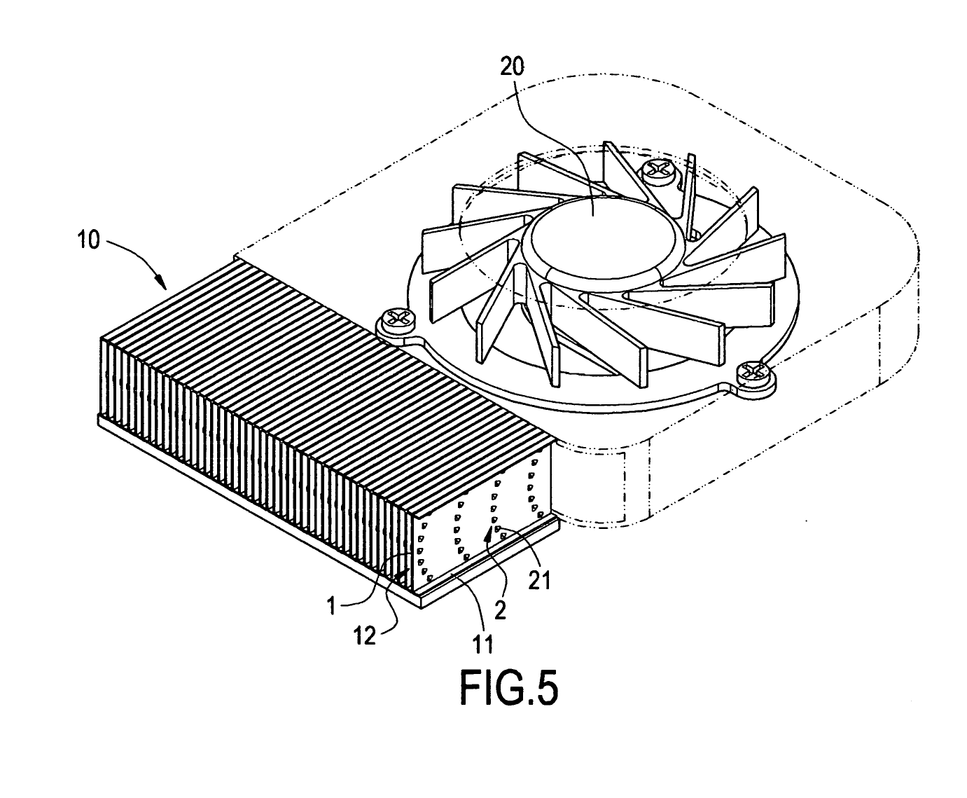

In the present invention, many heat-dissipating fins 1 are superposed on one another to form a heat-dissipating fin assembly 10, as shown in FIG. 5. A heat-dissipating fan 20 is mounted to the heat-dissipating fan 20 can be blown from the inlets of the heat-dissipating fins into each flowing path 12, so that the heat source can be dissipated from the outlet at the other side of the heat-dissipating fin to the outside.

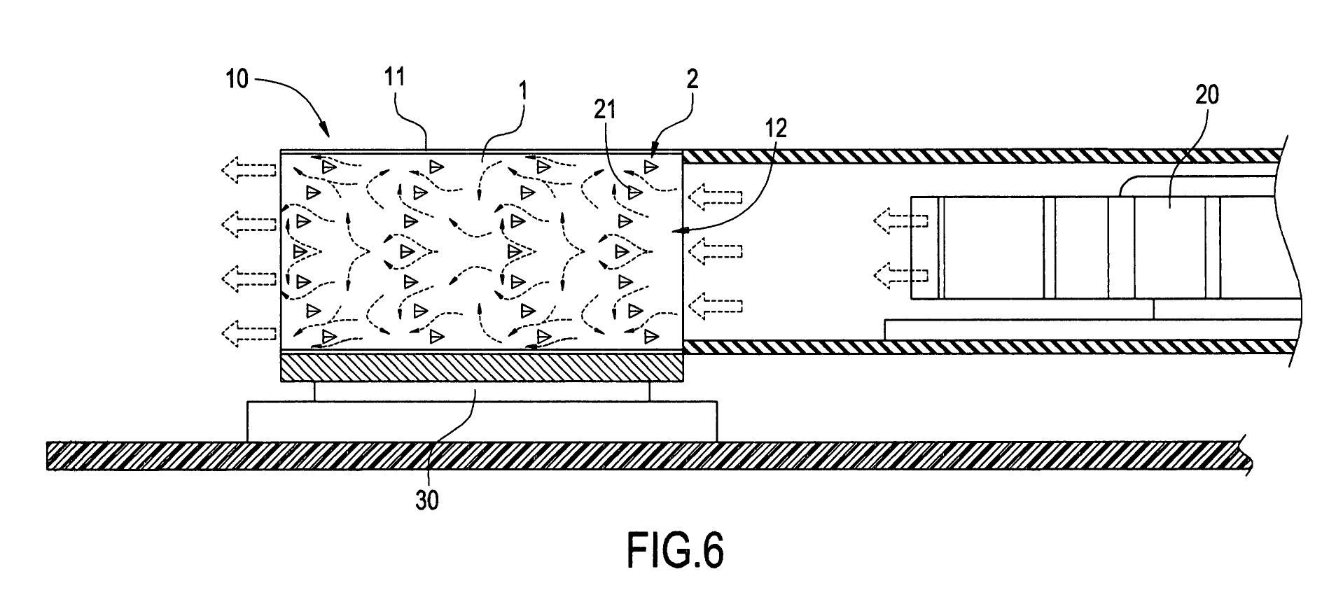

With reference to FIG. 6, the heat-dissipating fin assembly 10 can be mounted to a CPU 30. The, heat source generated by operation of the CPU 30 can be heat-exchanged to the heat-dissipating fins 1. At the same time, the cooling air generated by the heat-dissipating fan 20 enters the inlet of the heat-dissipating fin and passes through the flowing path 12. As soon as the cooling air contacts with the thorns 21 of the air-guiding portions 2, a three-dimensional turbulent flow can be formed in the back of each thorn 21. As a result, the duration within which the cooling air stays in the flowing path 12 can be extended to completely perform the heat exchange to carry the heat source out of the heat-dissipating fins 1.

According to the above description, the present invention provides plural sets of air-guiding portions 2 on each heat-dissipating fin 1, so that the external cooling air can be formed into a three-dimensional turbulent flow on the heat-dissipating fin 1. As a result, the duration within which the cooling air stays in the flowing path 12 can be extended to efficiently carry the heat source out of the heat-dissipating fins 1, thereby to greatly improve the efficiency in the heat dissipation.

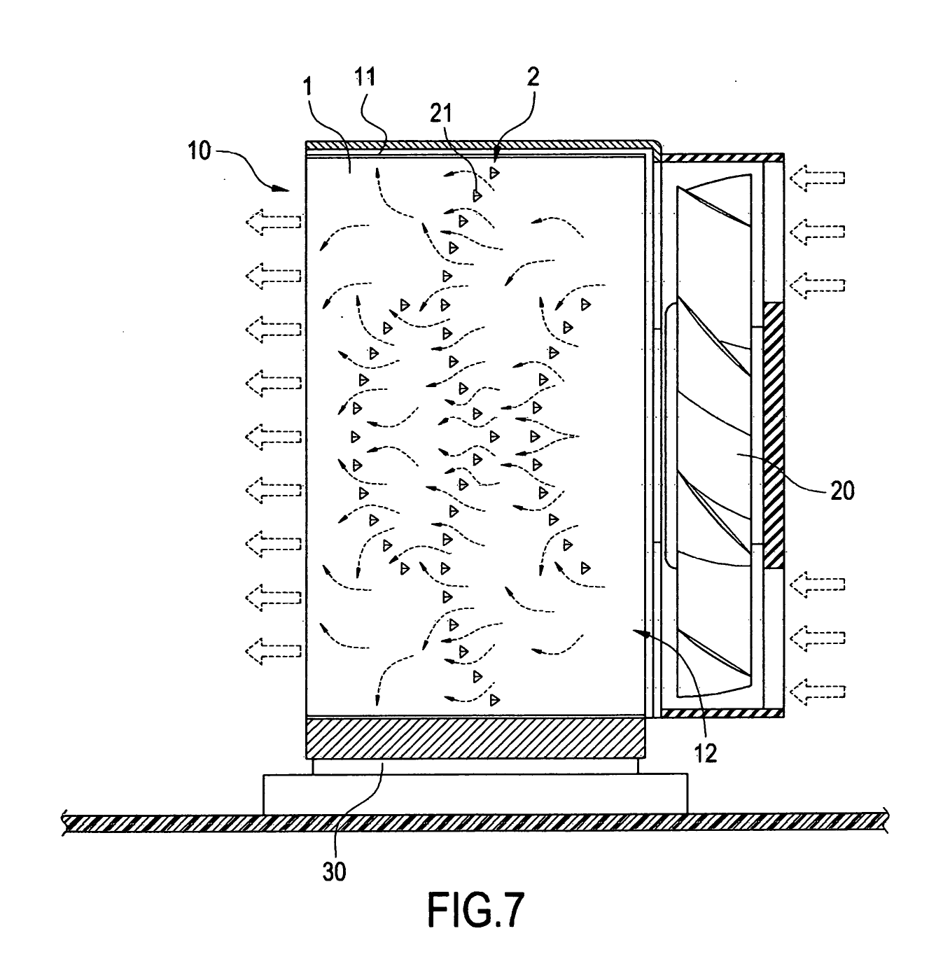

Alternatively, with reference to FIG. 7, the heat-dissipating fin 1 also defines two long sides and two short sides. Both short sides are bent toward the same direction to form two partitioning pieces. With the enclosure of the two partitioning pieces 11, a flowing path 12 is formed between two adjacent heat-dissipating fins 1. Both long sides are used to be an inlet and an outlet for external cooling air. Further, the heat-dissipating fan 20 can be an axial flow fan in order to increase the surface area for heat dissipation. Also, the fan can be arranged in various ways to correspond to the requirements for heat dissipation in different kinds of CPUs 30.

According to the above, the present invent indeed achieves the desired effects by employing the above structures. Further, since the construction of the present invention has not been published or put to public use prior to applying for patent, the present invention involves the novelty and inventive steps, and conforms to the requirements for a utility model patent.

Although the present invention has been described with reference to the foregoing preferred embodiments, it will be understood that the invention is not limited to the details thereof. Various equivalent variations and modifications can still be occurred to those skilled in this art in view of the teachings of the present invention. Thus, all such variations and equivalent modifications are also embraced within the scope of the invention as defined in the appended claims.

What is claimed is:

1. An air-guiding structure for a heat-dissipating fin, characterized in that:
the heat-dissipating fin is provided with plural sets of air-guiding portions, each air-guiding portion comprises a plurality of thorns made by stamping, the thorns are arranged non-linearly and oriented to face the inlet or the outlet for external cooling air.

2. The air-guiding structure for a heat-dissipating fin according to claim 1, wherein the heat-dissipating fin is manufactured by stamping a metallic plate to define two long sides and two short sides, both long sides are bent toward the same direction to form two partitioning pieces, with the enclosure of the two partitioning pieces, a flowing path is formed between two adjacent heat-dissipating fins, and both short sides are used to be an inlet and an outlet for external cooling air.

3. The air-guiding structure for a heat-dissipating fin according to claim 1, wherein the thorn is manufactured by stamping a through hole on the heat-dissipating fin with the unbroken portion connected to one side of the through hole.

4. The air-guiding structure for a heat-dissipating fin according to claim 1, wherein each air-guiding portion is arranged at the same interval.

5. The air-guiding structure for a heat-dissipating fin according to claim 1, wherein any two adjacent air-guiding portions are staggered.

6. The air-guiding structure for a heat-dissipating fin according to claim 1, wherein the air-guiding portions are arranged irregularly.

7. The air-guiding structure for a heat-dissipating fin according to claim 1, wherein the non-linear arrangement of the thorns is curved, and the concave of the curved arrangement faces the inlet.

8. The air-guiding structure for a heat-dissipating fin according to claim 1, wherein the non-linear arrangement of the thorns is “<”-shaped, and the concave of the “<”-shaped arrangement faces the inlet

9. The air-guiding structure for a heat-dissipating fin according to claim 1, wherein the non-linear arrangement of the thorns is “[”-shaped, and the concave of the “[”-shaped arrangement faces the inlet.

10. The air-guiding structure for a heat-dissipating fin according to claim 1, wherein the heat-dissipating fin is manufactured by stamping a metallic plate to define two long sides and two short sides, both short sides are bent toward the same direction to form two partitioning pieces, with the enclosure of the two partitioning pieces, a flowing path is formed between two adjacent heat-dissipating fins, and both long sides are used to be an inlet and an outlet for external cooling air.
